(19) United States
(12) Patent Application Publication
(10) Pub. No.: US 2009/0260861 A1
(43) Pub. Date: Oct. 22, 2009

(54) POLYCRYSTALLINE, MAGNETIC CERAMIC MATERIAL, MICROWAVE MAGNETIC DEVICE, AND NON-RECIPROCAL CIRCUIT DEVICE COMPRISING SUCH MICROWAVE MAGNETIC DEVICE

(75) Inventors: Hirokazu Nakajima, Tottori-ken (JP); Hiroyuki Itoh, Tottori-ken (JP)

Correspondence Address: SUGHRUE MION, PLLC, 2100 PENNSYLVANIA AVENUE, N.W., SUITE 800, WASHINGTON, DC, 20037, US

(73) Assignee: HITACHI METALS, LTD., Minato-ku, Tokyo (JP)

(21) Appl. No.: 12/092,777

(22) PCT Filed: Nov. 7, 2006
(86) PCT No.: PCT/JP2006/322200

§ 371 Date: May 6, 2008

(30) Foreign Application Priority Data
Nov. 7, 2005 (JP) 2005-321940

(51) Int. Cl. H05K 1/09; H01F 1/00

(52) U.S. Cl. 174/257; 252/62.57

(57) ABSTRACT

A polycrystalline, magnetic ceramic material having a basic composition represented by the general formula of (Y_{3-x-y-z}Bi_{X}Ca_{y}Gd_{z})(Fe_{5-α-β-γ-ε}In_{α}Al_{β}V_{γ}Zr_{ε})O₁₂, wherein 0.4<x≦1.5, 0.5≦y≦1, 0≦z≦0.5, y+z<1.3, 0≦α≦0.6, 0≦β≦0.45, 0.25≦γ≦0.5, 0≦ε≦0.25, and 0.15 ≦α+β≦0.75 each by an atomic ratio, which is predominantly composed of a phase having a garnet structure, and sinterable at a temperature of 850-1050° C.

### FIELD OF THE INVENTION

The present invention relates to a microwave, magnetic material used for high-frequency circuit devices, particularly to a polycrystalline, magnetic ceramic material capable of being simultaneously sintered with electrode materials such as silver and copper, etc.

### BACKGROUND OF THE INVENTION

Communications equipments using electromagnetic waves in a microwave band, such as cell phones, satellite broadcasting equipments, etc., have been getting increasingly smaller in recent years, resulting in increasing requirement of miniaturizing individual devices. Typical high-frequency circuit devices used in communications equipments are microwave, non-reciprocal circuit devices such as circulators, isolators, etc. The isolator does not substantially attenuates signals in a transmitting direction while largely attenuating them in an opposite direction, and is used in transmission/receiving circuits in mobile communications equipments in microwave and UHF bands, such as cell phones, etc.

The non-reciprocal circuit device such as a circulator and an isolator comprises a central conductor assembly comprising a microwave, magnetic body, and central conductors having pluralities of mutually insulated electrode lines, which are disposed closely on the microwave, magnetic body, and a permanent magnet for applying a DC magnetic field to the central conductor assembly. The central conductors, discrete from the microwave, magnetic body, are copper foils surrounding the microwave, magnetic body, or electrode patterns obtained from a silver paste printed and sintered on the microwave, magnetic body.

To meet the requirement of miniaturization, JP 6-61708 A proposes the integral sintering of a microwave, magnetic material, with central conductors formed on the microwave, magnetic material by a conductive paste comprising conductive powder such as palladium, platinum, etc. and an organic solvent, at a temperature of 1300-1600° C. Although palladium and platinum having as high a melting point as 1300° C. or higher is easily integrally sintered with the microwave, magnetic material, they have high specific resistance, resulting in large insertion loss when used for isolators, for instance.

When low-resistance silver and copper are used for the central conductor, the addition of Bi or a low-melting point glass to a polycrystalline, magnetic ceramic material may be contemplated to achieve sufficient simultaneous sintering. However, when Bi or a low-melting point glass is added to a microwave, magnetic material having a narrow single-phase range, undesired phases, pores, etc. are likely to be generated, failing to produce a low-loss, microwave, magnetic body.

In addition, a microwave, non-reciprocal circuit device combined with a permanent magnet is desired to have excellent magnetic characteristics, such that it has temperature characteristics for compensating the temperature characteristics of saturation magnetization 4 πMs of the permanent magnet.

### OBJECTS OF THE INVENTION

Accordingly, an object of the present invention is to provide a polycrystalline, magnetic ceramic material capable of being simultaneously sintered with silver or copper at a low temperature of 850-1050° C., and having excellent magnetic characteristics.

Another object of the present invention is to provide a polycrystalline, magnetic ceramic material capable of being simultaneously sintered with silver or copper at a low temperature of 850-1050° C., suffering from little formation of undesired phases even if Bi is contained, having a small ferromagnetic resonance half-width ΔH and dielectric loss (tan δ), and such a temperature coefficient αₘ as to compensate the temperature characteristics of saturation magnetization 4 πMs of a permanent magnet.

A further object of the present invention is to provide a microwave magnetic device integrally comprising an electrode pattern in and/or on a magnetic body made of such a polycrystalline, magnetic ceramic material.

A still further object of the present invention is to provide a non-reciprocal circuit device comprising such a microwave magnetic device.

### DISCLOSURE OF THE INVENTION

The polycrystalline, magnetic ceramic material of the present invention has a basic composition represented by the general formula of (Y_{3-x-y-z}BiₓCa_{y}Gd_{z})(Fe_{5-α-β-γ-ε}In_{α}Al_{β}V_{γ}Zr_{ε})O₁₂, wherein 0.4<x≦1.5, 0.5≦y≦1, 0≦z≦0.5, y+z<1.3, 0≦α≦0.6, 0≦β≦0.45, 0.25≦γ≦0.5, 0≦ε≦0.25, and 0.15≦α+β≦0.75 each by an atomic ratio, and is predominantly composed of a phase having a garnet structure and sinterable at a temperature of 850-1050° C.

The polycrystalline, magnetic ceramic material of the present invention preferably has saturation magnetization 4 πMs of 60-130 mT with a temperature coefficient αₘ, of −0.38%/° C. to −0.2%/° C., and a ferromagnetic resonance half-width ΔH of less than 20000 A/m.

The microwave magnetic device of the present invention comprises a microwave magnetic body, and electrode patterns formed in and/or on the microwave magnetic body, the microwave magnetic device being obtained by printing a conductive paste containing at least one selected from the group consisting of Ag, Cu, Ag alloys and Cu alloys in and/or on moldings of the above polycrystalline, magnetic ceramic material to form the electrode patterns, and integrally sintering them.

The non-reciprocal circuit device of the present invention comprises the above microwave magnetic body, central conductors constituted by the electrode patterns formed in the microwave magnetic body, capacitors connected to the central conductors, and a ferrite magnet for applying a DC magnetic field to the microwave magnetic body.

The ferrite magnet preferably has a residual magnetic flux density Br of 420 mT or more with a temperature coefficient of −0.15%/° C. to −0.25%/° C.

### BRIEF DESCRIPTION OF THE DRAWING

FIG. 1(a) is a perspective view showing an upper surface of a central conductor assembly used in a non-reciprocal circuit device according to an embodiment of the present invention.

FIG. 1(b) is a perspective view showing a rear surface of the central conductor assembly of FIG. 1(a).

FIG. 2 is an exploded view showing the internal structure of the central conductor assembly of FIG. 1.

FIG. 3 is an exploded perspective view showing a non-reciprocal circuit device according to an embodiment of the present invention.

FIG. 4 is a perspective view showing an upper surface of a central conductor assembly used in a non-reciprocal circuit device according to another embodiment of the present invention.

FIG. 5 is an exploded view showing the internal structure of the central conductor assembly of FIG. 4.

FIG. 6 is an exploded view showing the internal structure of a capacitor laminate used in a non-reciprocal circuit device according to another embodiment of the present invention.

FIG. 7 is an exploded perspective view showing a non-reciprocal circuit device according to another embodiment of the present invention.

FIG. 8 is a view showing the equivalent circuit of a non-reciprocal circuit device according to another embodiment of the present invention.

### DESCRIPTION OF THE PREFERRED EMBODIMENTS

[1] Polycrystalline, Magnetic Ceramic Material

(1) Composition

The polycrystalline, magnetic ceramic material of the present invention has a basic composition represented by the general formula of (Y_{3-x-y-z}BiₓCa_{y}Gd_{z})(Fe_{5-α-β-γ-ε}In_{α}Al_{β}V_{γ}Zr_{ε})O₁₂, wherein 0.4<x≦1.5, 0.5≦y≦1, 0≦z≦0.5, y+z<1.3, 0≦α≦0.6, 0≦β≦0.45, 0.25≦γ≦0.5, 0≦ε≦0.25, and 0.15≦α+β≦0.75 each by atomic ratio, and is predominantly composed of a phase having a garnet structure and sinterable at as low temperatures as 850-1050° C.

The sintering temperature, ferromagnetic resonance half-width ΔH, dielectric loss (tan δ), saturation magnetization 4 πMs and its temperature characteristics, etc. of the polycrystalline, magnetic ceramic material are greatly influenced by the basic composition.

When the Bi content x contributing to lowering the sintering temperature is 0.4 or less, sintering is difficult at 1050° C. or lower. When x>1.5, the sintering can be conducted at 850-1050° C., but undesired phases are likely to appear in the sintered body, resulting in dielectric loss (tan δ) of more than 15×10⁻⁴, and an extremely large ferromagnetic resonance half-width ΔH of more than 20000 A/m. Accordingly, the Bi content x meets 0.4<x≦1.5, preferably 0.5≦x≦0.9.

Ca added together with low-melting-point V prevents the evaporation of V during sintering. To exhibit this effect sufficiently, the Ca content y meets 0.5≦y≦1.

Gd contributes to the adjustment of the temperature coefficient αₘ of saturation magnetization 4 πMs. When the Gd content z exceeds 0.5, the temperature coefficient αₘ of saturation magnetization 4 πMs from −20° C. to +60° C. is likely to be less than −0.20%/° C., failing to compensate the temperature characteristics of the permanent magnet. Accordingly, the Gd content z meets 0≦z≦0.5.

Ca and Gd should meet the condition of y+z<1.3. When y+z is 1.3 or more, the temperature coefficient αₘ of saturation magnetization 4 πMs from −20° C. to +60° C. is likely to be less than −0.20%/C, failing to compensate the temperature characteristics of the permanent magnet.

In, Al, V and Zr contribute to the adjustment of the temperature coefficient αₘ of saturation magnetization 4 πMs and the lowering of the sintering temperature. The contents α, β, γ and ε of In, Al, V and Zr should meet the conditions of 0≦α≦0.6, 0≦β≦0.45, 0.25≦γ≦0.5, 0≦ε≦0.25, and 0.15≦α+β≦0.75. When the contents of In, Al, V and Zr are less than the above ranges, the sintering is difficult at 1050° C. or lower, resulting in saturation magnetization 4 πMs of more than 130 mT and insufficient magnetism of the permanent magnet. When the contents of In, Al, V and Zr are more than the above ranges, the saturation magnetization 4 πMs is less than 60 mT, failing to compensate the temperature characteristics of the permanent magnet.

The total amount of In and Al meets 0.15≦α+β≦0.75. When α+β<0.15, the polycrystalline, magnetic ceramic material has a dielectric loss (tan δ) of 15×10⁻⁴ or more, and an extremely large ferromagnetic resonance half-width ΔH of more than 20000 A/m. When 0.75<α+β, the temperature coefficient αₘ of saturation magnetization 4 πMs is less than −0.38%/° C. with a large absolute value, failing to compensate the temperature characteristics of the permanent magnet.

(2) Characteristics

Because the polycrystalline, magnetic ceramic material having the above basic composition is sinterable at low temperatures of 850-1050° C., it can be sintered integrally with electrodes made of a high-conductivity metal such as silver and copper. Because the polycrystalline, magnetic ceramic material has saturation magnetization 4 πMs of 60-130 mT (temperature coefficient αₘ=−0.38%/° C. to −0.2%/° C.), and a ferromagnetic resonance half-width ΔH of 20000 A/m or less, a microwave magnetic body of extremely low loss due to a high Q value of the magnetic material and the electric resistance of electrodes can be obtained. When the magnetic material is used for a microwave, non-reciprocal circuit device such as an isolator, a circulator, etc., excellent microwave characteristics and low loss can be achieved.

[2] Production Method of Polycrystalline Ceramic Magnetic Body

Starting materials such as yttrium oxide (Y₂O₃), bismuth oxide (Bi₂O₃), calcium carbonate (CaCO₃), gadolinium oxide (Gd₂O₃), iron oxide (Fe₂O₃), indium oxide (In₂O₃), aluminum oxide (Al₂O₃), vanadium oxide (V₂O₅) and zirconium oxide (ZrO₂) are mixed with a solvent such as water, etc., wet-blended by a ball mill, etc. for 20-50 hours, and then dried. The mixed powder is calcined at a temperature of 800-900° C. for 1.5-2 hours. The calcining temperature is preferably lower than the subsequent sintering temperature by 50° C. more. The calcined powder is mixed with a solvent such as water, etc., wet-pulverized by a ball mill, etc. for 20-30 hours, and then dried. The resultant magnetic ceramic composition powder preferably has an average particle size of 0.5-2 μm. The magnetic ceramic composition powder is mixed with a binder and a solvent such as water, an organic solvent, etc., and molded at a pressure of 1-2 ton/cm². The resultant molding is sintered at a temperature of 850-1050° C.

[3] Simultaneous Sintering with Electrode Materials

The above magnetic ceramic composition powder is blended with a binder and a solvent such as water, an organic solvent, etc. to prepare a moldable material, which is formed into pluralities of green sheets. After provided with via-holes, if necessary, green sheets are printed with a conductive paste, overlapped, and pressure-bonded while heating, and the resultant laminate is sintered at a temperature of 850-1050° C. The sintering of the magnetic ceramic composition and the sintering of the conductive paste simultaneously occur to provide a magnetic ceramic laminate (microwave magnetic device) integrally having electrodes.

[4] Central Conductor Assembly and Non-Reciprocal Circuit Device

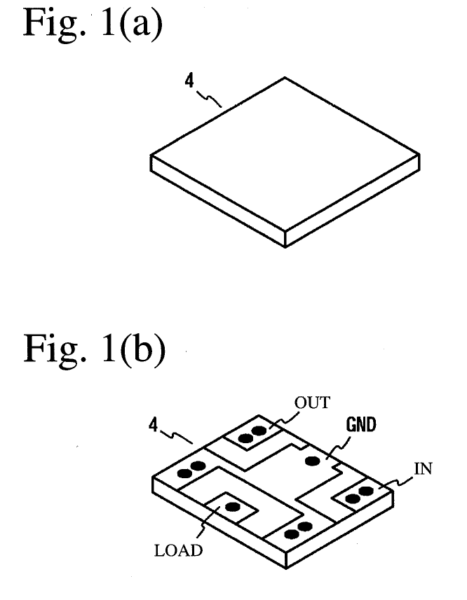

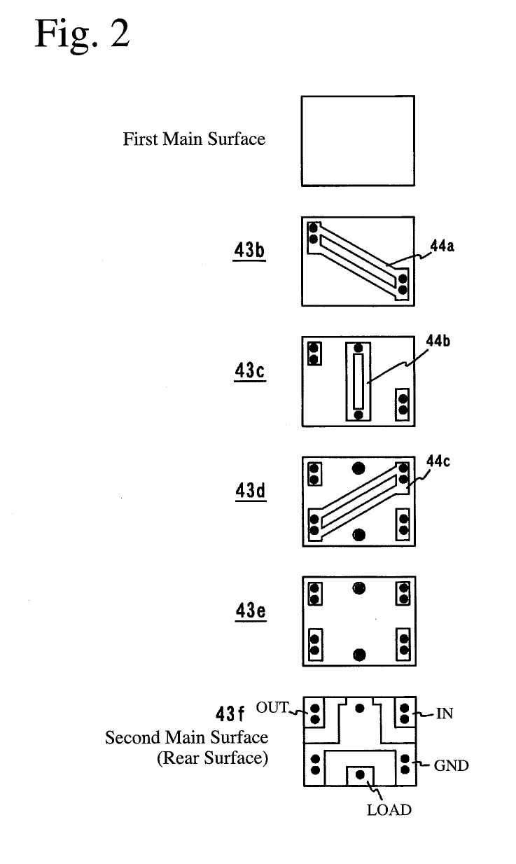

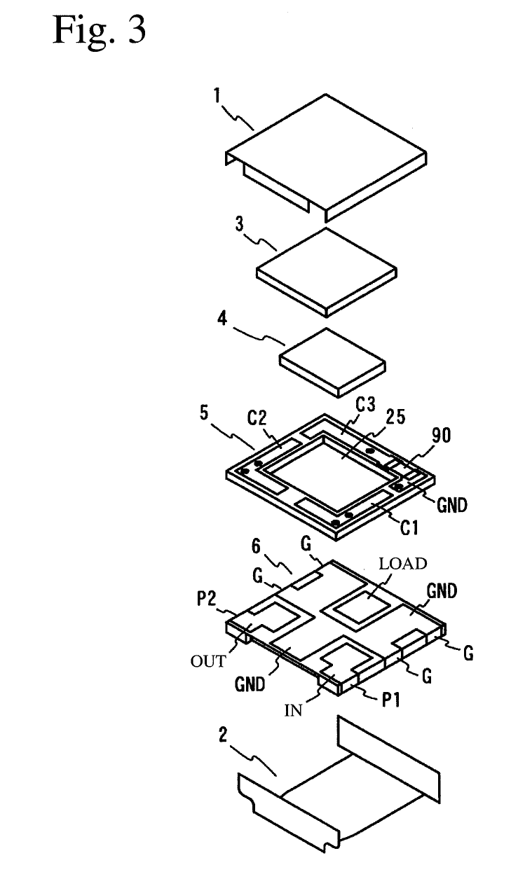

FIG. 1 shows the appearance of a microwave magnetic device (central conductor assembly) used in a non-reciprocal circuit device according to one embodiment of the present invention, and FIG. 2 shows its internal structure. FIG. 3 shows the internal structure of a non-reciprocal circuit device according to an embodiment of the present invention. This non-reciprocal circuit device comprises a central conductor assembly 4, a capacitor laminate 5 having a center opening for receiving the central conductor assembly 4, a resistor 90 in the form of a chip or a resistor film mounted on the capacitor laminate 5, a permanent magnet 3 applying a DC magnetic field to the central conductor assembly 4, upper and lower magnetic metal cases 1, 2 functioning as a magnetic yoke, and a resin substrate 6 disposed between the capacitor laminate 5 and the lower case 2. The resin substrate 6 comprises terminals connected to a circuit board, and electrodes connecting the central conductor assembly 4 to the capacitor laminate 5.

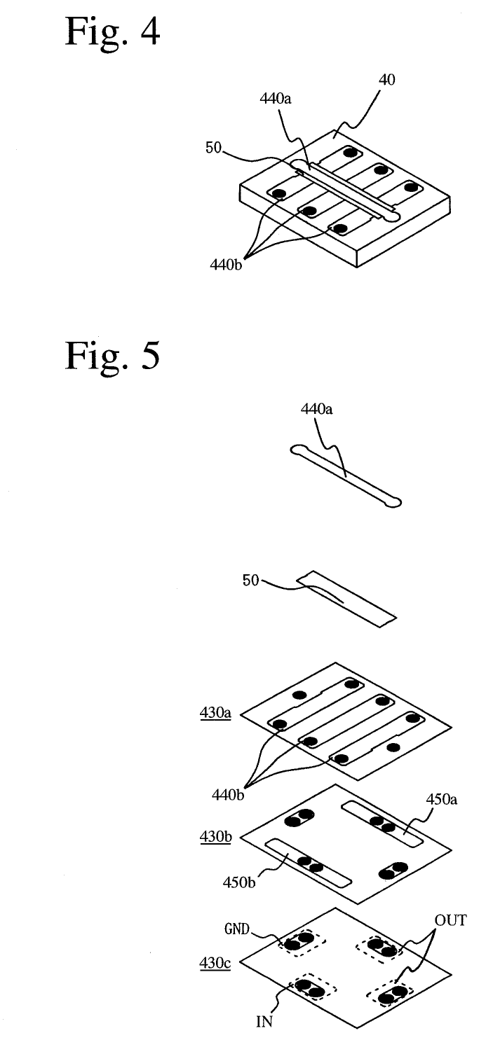

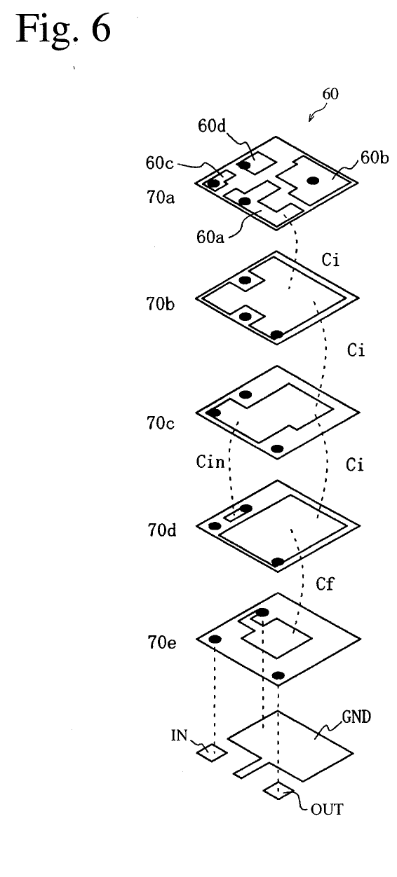

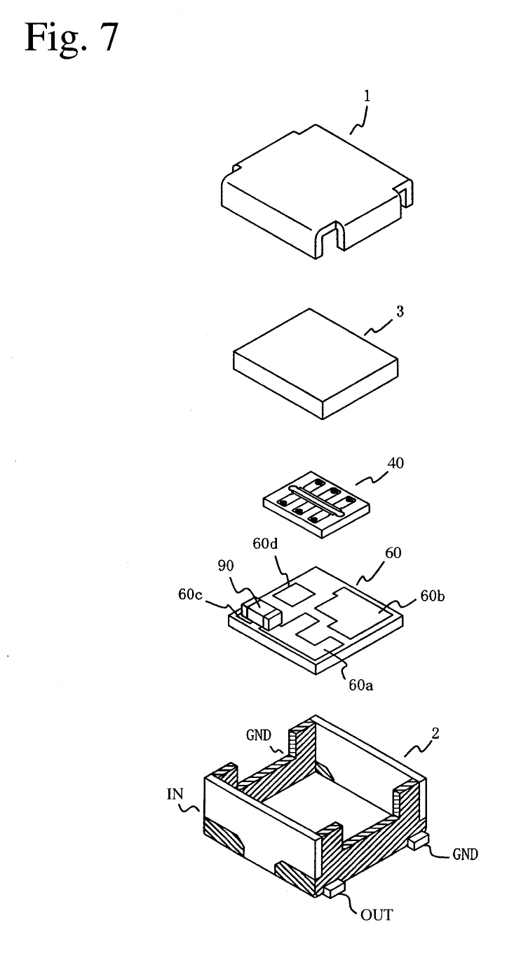

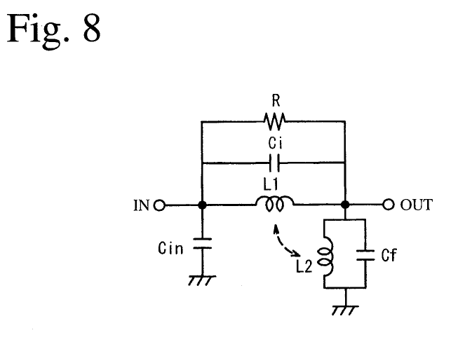

FIG. 4 shows the appearance of a microwave magnetic device (central conductor assembly) used in a non-reciprocal circuit device according to another embodiment of the present invention, and FIG. 5 shows its internal structure. FIG. 6 shows the internal structure of a capacitor laminate used in the non-reciprocal circuit device according to another embodiment of the present invention. FIG. 7 shows the internal structure of the non-reciprocal circuit device according to another embodiment of the present invention, and FIG. 8 shows its equivalent circuit. This non-reciprocal circuit device comprises a central conductor assembly 4, a capacitor laminate 60 mounting the central conductor assembly 40 and a resistor 90 in the form of a chip or a resistor film, a permanent magnet 3 applying a DC magnetic field to the central conductor assembly 40, and upper and lower magnetic metal cases 1, 2 functioning as a magnetic yoke.

The present invention will be explained in more detail referring to Examples below without intention of restricting the present invention thereto.

### Example 1

Gd₂O₃, Y₂O₃, CaCO₃, Bi₂O₃, Fe₂O₃, In₂O₃, V₂O₅, Al₂O₃ and ZrO₂ each having a purity of 99.0% or more were formulated as starting materials in the composition shown in Table 1, mixed with ion-exchanged water to a slurry concentration of 40% by mass, wet-blended by a ball mill for 40 hours, and then dried. The resultant powder was calcined at a temperature of 825° C. for 2 hours. The calcined powder was mixed with ion-exchanged water to a slurry concentration of 40% by mass, wet-pulverized by a ball mill for 24 hours, and then dried. The resultant magnetic ceramic composition powder had an average particle size of 0.7 μm. This magnetic ceramic composition powder was mixed with an aqueous solution of a binder (PVA), and blended to obtain granulated powder, which was molded to a disc of 14 mm in diameter and 7 mm in thickness at a pressure of 2 ton/cm². This molding was sintered at the temperature shown in Table 1 for 8 hours in the air.

TABLE 1

| | Main Components (by atomic ratio) | | | | | | | |
|---|---|---|---|---|---|---|---|---|
| | Y site | | | Fe site | | | | Sintering |
| Sample | Bi | Ca | Gd | In | Al | V | Zr | Temperature |
| No. | (x) | (y) | (z) | (α) | (β) | (γ) | (ε) | (° C.) |
| *1 | 0.40 | 0.80 | 0.50 | 0.20 | 0.00 | 0.40 | 0.00 | 1250 |
| 2 | 0.50 | 0.80 | 0.40 | 0.20 | 0.00 | 0.40 | 0.00 | 1050 |
| *3 | 1.25 | 0.80 | 0.50 | 0.20 | 0.00 | 0.40 | 0.00 | 900 |
| *4 | 1.60 | 0.80 | 0.50 | 0.20 | 0.00 | 0.40 | 0.00 | 850 |
| *5 | 1.00 | 0.00 | 0.50 | 0.20 | 0.00 | 0.00 | 0.00 | 1070 |
| 6 | 0.85 | 0.80 | 0.00 | 0.40 | 0.00 | 0.40 | 0.00 | 920 |
| 7 | 0.85 | 0.80 | 0.00 | 0.60 | 0.00 | 0.40 | 0.00 | 920 |
| 8 | 0.85 | 0.60 | 0.00 | 0.20 | 0.00 | 0.30 | 0.00 | 920 |
| 9 | 0.85 | 1.00 | 0.00 | 0.20 | 0.00 | 0.50 | 0.00 | 920 |
| *10 | 0.85 | 0.80 | 0.00 | 0.00 | 0.00 | 0.40 | 0.00 | 900 |
| *11 | 0.85 | 0.80 | 0.00 | 0.00 | 0.00 | 0.40 | 0.20 | 920 |
| *12 | 0.85 | 0.80 | 0.00 | 0.00 | 0.00 | 0.40 | 0.40 | 920 |
| *13 | 0.85 | 0.80 | 0.00 | 0.00 | 0.00 | 0.40 | 0.60 | 920 |
| 14 | 0.85 | 0.70 | 0.00 | 0.25 | 0.40 | 0.35 | 0.00 | 920 |
| 15 | 0.85 | 0.70 | 0.00 | 0.00 | 0.40 | 0.35 | 0.25 | 920 |
| 16 | 0.85 | 0.70 | 0.00 | 0.35 | 0.40 | 0.35 | 0.00 | 920 |
| 17 | 0.85 | 0.56 | 0.00 | 0.27 | 0.45 | 0.28 | 0.00 | 920 |
| 18 | 0.85 | 0.66 | 0.00 | 0.30 | 0.40 | 0.33 | 0.00 | 920 |
| 19 | 0.85 | 0.66 | 0.00 | 0.30 | 0.40 | 0.33 | 0.00 | 920 |
| 20 | 0.85 | 0.70 | 0.00 | 0.30 | 0.40 | 0.35 | 0.00 | 920 |
| 21 | 0.70 | 0.70 | 0.00 | 0.30 | 0.40 | 0.35 | 0.00 | 980 |
| 22 | 0.85 | 0.70 | 0.00 | 0.20 | 0.30 | 0.35 | 0.00 | 920 |
| 23 | 0.87 | 0.84 | 0.20 | 0.18 | 0.00 | 0.42 | 0.00 | 920 |
| 24 | 0.87 | 0.82 | 0.23 | 0.19 | 0.00 | 0.41 | 0.00 | 920 |
| 25 | 0.87 | 0.80 | 0.25 | 0.20 | 0.00 | 0.40 | 0.00 | 920 |
| 26 | 1.50 | 0.80 | 0.40 | 0.20 | 0.00 | 0.40 | 0.00 | 920 |
| *27 | 0.85 | 0.80 | 0.60 | 0.20 | 0.00 | 0.40 | 0.00 | 920 |
| *28 | 0.85 | 0.56 | 0.00 | 0.20 | 0.55 | 0.28 | 0.00 | 920 |

Note:
Samples with * were outside the scope of the present invention.

A cylindrical dielectric resonator of 11 mm in diameter and 5.5 mm in thickness was formed from the sintered body, and its dielectric loss (tan δ) was measured by a Hakki-Coleman method. The saturation magnetization Ms of the sintered body was measured by a vibrating sample magnetometer. The sintered body was machined to a disc of 5 mm in diameter and 0.2 mm in thickness, whose ferromagnetic resonance half-width ΔH was measured by a short-circuited coaxial cable method. The results are shown in Table 2.

TABLE 2

| Sample | 4πMs | αₘ | tan δ | ΔH |
|---|---|---|---|---|
| No. | (mT) | (%/° C.) | (×10⁻⁴) | (A/m) |
| *1 | 100 | −0.17 | 7.0 | 4100 |
| 2 | 100 | −0.22 | 7.5 | 5500 |
| *3 | 104 | −0.18 | 15.5 | 20000 |
| *4 | 101 | −0.17 | 32.0 | 29000 |
| *5 | 158 | −0.29 | 58.0 | 15000 |
| 6 | 125 | −0.30 | 10.0 | 12800 |
| 7 | 127 | −0.34 | 11.0 | 18000 |
| 8 | 135 | −0.25 | 12.5 | 5600 |
| 9 | 101 | −0.25 | 11.5 | 12400 |
| *10 | 103 | −0.20 | 17.0 | 16000 |
| *11 | 125 | −0.25 | 15.0 | 21000 |
| *12 | 120 | −0.25 | 19.0 | 24000 |
| *13 | 111 | −0.25 | 25.0 | 21000 |
| 14 | 77 | −0.33 | 14.0 | 11000 |
| 15 | 77 | −0.32 | 13.0 | 17000 |
| 16 | 79 | −0.38 | 13.0 | 9500 |
| 17 | 82 | −0.34 | 14.0 | 12000 |
| 18 | 85 | −0.34 | 13.5 | 10500 |
| 19 | 85 | −0.35 | 9.5 | 9800 |
| 20 | 80 | −0.35 | 9.9 | 7700 |
| 21 | 81 | −0.36 | 9.0 | 5900 |
| 22 | 87 | −0.29 | 7.5 | 10000 |
| 23 | 97 | −0.24 | 8.5 | 7500 |
| 24 | 102 | −0.23 | 8.0 | 8000 |
| 25 | 109 | −0.22 | 7.5 | 8500 |
| 26 | 101 | −0.21 | 10.0 | 13000 |
| *27 | 112 | −0.18 | 12.0 | 25000 |
| *28 | 58 | −0.36 | 10.0 | 15000 |

Note:
Samples with * are outside the scope of the present invention.

As is clear from Tables 1 and 2, a dense sintered body was not obtained at a sintering temperature of 1050° C. or lower in Sample No. 1 outside the range of 0.4<x≦1.5. The temperature coefficient αₘ of saturation magnetization 4 πMs was −0.20%/° C. or less at −20° C. to +60° C. in Sample Nos. 3, 4 and 27 outside the range of y+z<1.3. Sample No. 5, whose y and γ were outside the ranges of the present invention, had a dielectric loss (tan δ) exceeding 15×10⁻⁴ and a magnetic resonance half-width ΔH exceeding 20000 A/m. Sample Nos. 10-13, in which α+β<0.2, had a dielectric loss (tan δ) of 15×10⁻⁴ or more, and as extremely large a ferromagnetic resonance half-width ΔH as 20000 A/m or more. Particularly Sample Nos. 12 and 13, in which ε>0.25, had as extremely large tan δ as 19×10⁻⁴ or more. Sample No. 28, in which β>0.45, had saturation magnetization 4 πMs of less than 60 mT.

On the other hand, dense sintered bodies were obtained at a temperature of 850-1050° C. in Samples within the scope of the present invention, which had dielectric losses (tan δ) of 15×10⁻⁴ or less and ferromagnetic resonance half-widths ΔH of less than 20000 A/m. Their temperature coefficients αₘ of saturation magnetization 4 πMs were −0.38%/° C. to −0.2%/° C. at −20° C. to +60° C., compensating the temperature characteristics of permanent magnets.

### Example 2

Central conductors were laminated on a rectangular microwave magnetic body having opposing first and second main surfaces and side surfaces connecting both main surfaces to produce a central conductor assembly 4 having the structure shown in FIGS. 4 and 5 by the following process. First, starting materials comprising Y₂O₃, Bi₂O₃, CaCO₃, Fe₂O₃, In₂O₃, Al₂O₃ and V₂O₅ having the composition of Sample No. 20 shown in Table 1 were wet-mixed by a ball mill. The resultant slurry was dried, calcined at a temperature of 850° C., and then wet-pulverized by a ball mill to produce polycrystalline, magnetic ceramic material powder having the formula of (Y_{1.45}Bi_{0.85}Ca_{0.7})(Fe_{3.95}In_{0.3}Al_{0.4}V_{0.35})O₁₂ (by atomic ratio). This magnetic material powder was mixed with an organic binder (polyvinyl butyral, PVB), a plasticizer (butylphthalyl butylglycolate, BPBG), and an organic solvent (ethanol and butanol) in a ball mill, adjusted in viscosity, and formed into magnetic ceramic green sheets of 40 μm and 80 μm, respectively, in thickness by a doctor blade method.

Each ceramic green sheet 430a-430c was provided with via-holes (shown by black circles in the figure) of 0.1 mm in diameter by a laser, and printed with a conductive Ag paste to form central conductors as follows. A central conductor 440b (L1 in the equivalent circuit) constituted by three electrode fingers was formed on the first main surface of the ceramic green sheet 430a, and a central conductor 440a (L2 in the equivalent circuit) was formed thereon via a ribbon-shaped glass paste 50. The ceramic green sheet 430b was provided with electrodes 450a, 450b connected to the central conductor 440b. A ground electrode GND and input/output electrodes IN, OUT were formed on the second main surface of the ceramic green sheet 430c. Pluralities of ceramic green sheets having via-holes were disposed between the ceramic green sheets 430b and 430c, though omitted in the figure. Pluralities of green sheets 430a-430c having electrode patterns were overlapped, and pressure-bonded at 80° C. and 12 MPa to provide a laminate.

The laminate was cut to a predetermined size, and sintered at 920° C. for 8 hours. The central conductors 440a, 440b were connected to the ground electrode GND and the input/output electrodes IN, OUT through via-holes filled with an Ag conductor. Thus obtained was a central conductor assembly 40 of 1.4 mm×1.2 mm×0.2 mm in external size, which had the central conductors 440a, 440b crossing with insulation, and the ground electrode GND and the input/output electrodes IN, OUT as a land grid array (LGA) on the second main surface.

Electrodes 60a-60d for mounting the central conductor assembly 40 and the terminal resistor 90 were formed on an upper surface of the capacitor laminate 60 having an external size of 2.0 mm×2.0 mm×0.2 mm, and connected to electrodes for matching capacitors in the capacitor laminate 60 through via-holes to produce capacitors Cin, Ci and Cf. Formed on a rear surface of the capacitor laminate 60 were input/output electrodes IN, OUT and a ground electrode GND, which were connected to the lower case 2.

The lower case 2 was formed from a thin, magnetic metal plate (SPCC) of 0.1 mm in thickness integrally insert-molded with a liquid crystal polymer (shown by hatching in the figure). The lower case 2 had a flat inner surface (to be connected to the capacitor laminate 60), on which connecting electrodes (not shown) were formed. The lower case 2 was provided on the side surfaces with mounting terminals IN, OUT, GND formed by the same thin, magnetic metal plate (SPCC) as that of the connecting electrodes.

A square permanent magnet 3 of 2.1 mm×1.8 mm×0.4 mm, which was made of La—Co-containing ferrite magnet (YBM-9BE available from Hitachi Metals, Ltd.), had a residual magnetic flux of 430-450 mT (temperature coefficient: −0.20% to −0.18%). It should be noted that the permanent magnet 3 need not be square but may be in a shape of a disc, a hexagon, etc. The same is true of the shape of the microwave magnetic device.

After the central conductor assembly 40 was disposed on the capacitor laminate 60, the permanent magnet 3 was disposed on the central conductor assembly 40, and they were covered with the upper and lower cases 1, 2 to provide a non-reciprocal circuit device having an external size of 2.5 mm×2.5 mm×1.2 mm. This non-reciprocal circuit device was evaluated with respect to the temperature characteristics of insertion loss and isolation. The results are shown in Table 3. This non-reciprocal circuit device exhibited small insertion loss variation due to the temperature change at every frequency, thus having excellent temperature characteristics.

TABLE 3

| Frequency | Insertion Loss (dB) | | | Isolation (dB) | | |
|---|---|---|---|---|---|---|
| (MHz) | −35° C. | +25° C. | +85° C. | −35° C. | +25° C. | +85° C. |
| 1920 | 0.35 | 0.39 | 0.52 | 21.5 | 19.5 | 15.6 |
| 1950 | 0.36 | 0.41 | 0.53 | 15.9 | 15.1 | 15.2 |
| 1980 | 0.41 | 0.47 | 0.58 | 11.5 | 11.5 | 13.1 |

### EFFECT OF THE INVENTION

The polycrystalline, magnetic ceramic material of the present invention can be simultaneously sintered with low-resistance metals such as silver and copper at as low temperatures as 850-1050° C. It also does not contain undesired phases despite the inclusion of Bi, exhibiting small ferromagnetic resonance half-width ΔH and dielectric loss (tan δ). Such polycrystalline, magnetic ceramic material is suitable for microwave magnetic devices used in microwave, non-reciprocal circuit devices such as circulators, isolators, etc., providing excellent microwave characteristics and low loss.

1. A polycrystalline, magnetic ceramic material having a basic composition represented by the general formula of (Y_{3-x-y-z}BiₓCa_{y}Gd_{z})(Fe_{5-α-β-γ-ε}In_{α}Al_{β}V_{γ}Zr_{ε})O₁₂, wherein 0.4<x≦1.5, 0.5≦y≦1, 0≦z≦0.5, y+z<1.3, 0≦α≦0.6, 0≦β≦0.45, 0.25≦γ≦0.5, 0≦ε≦0.25, and 0.15≦α+β≦0.75 each by an atomic ratio, which is predominantly composed of a phase having a garnet structure, and sinterable at a temperature of 850-1050° C.

2. The polycrystalline, magnetic ceramic material according to claim 1, which has saturation magnetization 4 πMs of 60-130 mT with a temperature coefficient αₘ of −0.38%/° C. to −0.2%/° C., and a ferromagnetic resonance half-width ΔH of less than 20000 A/m.

3. A microwave magnetic device comprising a microwave magnetic body, and electrode patterns formed in and/or on said microwave magnetic body, which is obtained by printing a conductive paste containing at least one selected from the group consisting of Ag, Cu, Ag alloys and Cu alloys in and/or on moldings of the polycrystalline, magnetic ceramic material recited in claim 1 to form said electrode patterns, and integrally sintering them.

4. A non-reciprocal circuit device comprising the microwave magnetic device recited in claim 3, wherein said electrode patterns constitute central conductors, and wherein said non-reciprocal circuit device further comprises capacitors connected to said central conductors, and a ferrite magnet for applying a DC magnetic field to said microwave magnetic device.

5. The non-reciprocal circuit device according to claim 4, wherein said ferrite magnet had a residual magnetic flux density Br of 420 mT or more with a temperature coefficient of −0.15%/° C. to −0.25%/° C.
